(19) United States
(12) Patent Application Publication
(10) Pub. No.: US 2020/0131396 A1
(43) Pub. Date: Apr. 30, 2020

(54) COMPOSITION FOR SEMICONDUCTOR ENCAPSULANT

(71) Applicant: Samsung Electronics Co., Ltd., Suwon-si (KR)

(72) Inventors: Eun Sil KANG, Suwon-si (KR); Joung Phil LEE, Suwon-si (KR)

(21) Appl. No.: 16/376,228

(22) Filed: Apr. 5, 2019

(30) Foreign Application Priority Data
Oct. 29, 2018 (KR) 10-2018-0129799

(51) Int. Cl. C09D 163/04; C09D 7/62; H01L 23/29; H01L 23/31; H01L 23/00; H01L 25/065

(52) U.S. Cl. CPC C09D 163/04; C09D 7/62; H01L 23/295; H01L 23/3128; H01L 23/562; H01L 2924/3511; H01L 25/0657; H01L 2224/73265; H01L 2225/06513; H01L 2225/06541; H01L 2225/06586; H01L 24/73

(57) ABSTRACT

A composition for a semiconductor encapsulant includes an epoxy resin, a curing agent, a filler, and a polyrotaxane, wherein the polyrotaxane includes a linear polymer A, an end group B, and a cyclic molecule C threaded through by the linear polymer. The cyclic molecule C has at least one functional group selected from the group consisting of an epoxy group, an oxetane group, and an alkoxysilyl group, or has a functional group capable of reacting with the at least one functional group.

### CROSS-REFERENCE TO RELATED APPLICATION(S)

This application claims the benefit of priority under 35 U.S.C. § 119 to Korean Patent Application No. 10-2018-0129799, filed on Oct. 29, 2018, in the Korean Intellectual Property Office, the disclosure of which is incorporated herein by reference in its entirety.

### BACKGROUND

### 1. Field

The present inventive concept relates to a composition for a semiconductor encapsulant, having high toughness and reduced warpage characteristics.

### 2. Description of Related Art

Epoxy resin is typically used as a semiconductor encapsulant due to high strength and excellent properties in terms of bonding strength, thermal characteristics, chemical resistance, processibility, and the like; however, epoxy resin may be susceptible to external impacts due to high brittleness. In particular, when repeatedly exposed to large temperature differences, such as in a temperature cycling test (TCT), epoxy resin may suffer fractures due to thermomechanical loading. To address this problem, rubber additives or elastomers are typically added to epoxy resin to induce stress relaxation.

Conventionally-used elastomers have a linear structure having functional groups capable of forming crosslinks with epoxy resin or with a curing agent, or other functional groups, bonded to ends or side chains thereof. In particular, when such functional groups, which are capable of forming crosslinks with the epoxy resin or with a curing agent, are insufficiently included, the elastomer component in the composition may separate from a resin mixture and bleed out to the surface of a semiconductor package through gaps formed with dies, thus giving rise to appearance defects during high-temperature processes such as a reflow process. On the other hand, when such functional groups are excessively included, sufficient crosslinks may be formed with the epoxy resin, thus not resulting in the issue of bleeding out to the surface of the semiconductor package; however, fixed crosslinks formed thereby may diminish the stress relaxation effect of elastomers, and may adversely affect layer formation and wetting of other materials in a subsequent process.

### SUMMARY

An aspect of the present inventive concept is to provide a composition for a semiconductor encapsulant capable of improving toughness and reducing warpage without causing appearance defects, by allowing crosslinked sites to move freely after curing epoxy resin.

According to certain example embodiments, the disclosure is directed to a semiconductor package, comprising: a substrate; at least one semiconductor chip on the substrate; and a semiconductor encapsulant covering the at least one semiconductor chip, wherein the semiconductor encapsulant comprises: an epoxy resin; a curing agent; a filler; and a polyrotaxane, wherein the polyrotaxane includes a linear polymer A, an end group B, and a cyclic molecule C threaded through by the linear polymer A, and wherein the cyclic molecule C has at least one functional group selected from the group consisting of an epoxy group, an oxetane group, and an alkoxysilyl group, or has a functional group capable of reacting with the at least one functional group.

According to certain example embodiments, the disclosure is directed to an epoxy resin composition comprising: an epoxy resin; a curing agent; a filler; and a polyrotaxane, wherein the polyrotaxane includes a linear polymer A, an end group B, and a cyclic molecule C threaded through by the linear polymer A, and wherein the cyclic molecule C has at least one functional group selected from the group consisting of an epoxy group, an oxetane group, and an alkoxysilyl group, or has a functional group capable of reacting with the at least one functional group.

According to certain example embodiments, the disclosure is directed to an epoxy resin composition, comprising: an epoxy resin; a curing agent; a filler; and a polyrotaxane, wherein the polyrotaxane includes a linear polymer A, an end group B, and a cyclic molecule C threaded through by the linear polymer A, wherein the linear polymer A is a polysiloxane, a polyethylene glycol, a polybutadiene, or a combination thereof, wherein the end group B is at least one selected from the group consisting of an adamantyl group, a silsesquioxanyl group, a phenyl group, a substituted or unsubstituted benzyl group, a cyclodextrinyl group, and a silane group, and wherein the cyclic molecule C has at least one functional group selected from the group consisting of an epoxy group, an oxetane group, and an alkoxysilyl group, or has a functional group capable of reacting with the at least one functional group.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 illustrates behaviors of a polyrotaxane according to an example embodiment of the present inventive concept, and crosslinks formed by the polyrotaxane;

FIG. 2 illustrates polyrotaxanes of different types, according to an example embodiment of the present inventive concept;

FIG. 3 is a graph illustrating stress-expansion ratios of an encapsulant, according to an example embodiment of the present inventive concept and Comparative Examples;

FIG. 4 is a graph showing a degree of warpage of a semiconductor encapsulant, predicted on the basis of the Young's modulus and the coefficient of thermal expansion of a composition for an encapsulant, according to an example embodiment of the present inventive concept;

FIG. 5 is a cross-sectional view of a structure of a semiconductor package that can be employed with an encapsulant, according to an example embodiment of the present inventive concept; and

FIG. 6 is a cross-sectional view of an integrated circuit device including a semiconductor package that can be employed with an encapsulant, according to an example embodiment of the present inventive concept.

### DETAILED DESCRIPTION

Hereinafter, example embodiments of the present inventive concept will be described with reference to the accompanying drawings.

According to an example embodiment, a composition for a semiconductor encapsulant may include an epoxy resin, a curing agent, a filler, and a crosslinking agent, and may further include a curing catalyst for shortening a curing time of the composition for a semiconductor encapsulant, and may even further include an additive for improving properties of the semiconductor encapsulant.

In the composition for a semiconductor encapsulant according to the example embodiment, the epoxy resin may be included for curing and bonding, and may be a compound containing at least one epoxy group per molecule, and may react with a hydroxyl group, an amino group, and an anhydrous group bonded to a cyclic molecule C of a polyrotaxane used as a crosslinking agent, to form crosslinks.

For example, for the epoxy resin, a liquid epoxy resin, a solid epoxy resin, or a mixture thereof may be used.

For example, the liquid epoxy resin may include one, or a mixture of two or more, selected from the group consisting of a bisphenol A liquid epoxy resin, a bisphenol F liquid epoxy resin, a tri- or more-functional liquid epoxy resin, a rubber-modified liquid epoxy resin, a urethane-modified liquid epoxy resin, an acrylic-modified liquid epoxy resin, and a photosensitive liquid epoxy resin. More preferably, the liquid epoxy resin may include a bisphenol A liquid epoxy resin.

For the solid epoxy resin, an epoxy resin that is solid or near-solid at room temperature while having one or more functional groups, and preferably has a softening point of 30-100° C. may be used. For example, the solid epoxy resin may include one, or a mixture of two or more, selected from the group consisting of a bisphenol-based epoxy resin, a phenol novolac-based epoxy resin, an o-cresol novolac-based epoxy resin, a polyfunctional epoxy resin, an amine-based epoxy resin, a heterocycle-containing epoxy resin, a polycyclic aromatic epoxy resin, a substituted epoxy resin, a naphthol-based epoxy resin, a dicyclopentadiene-based epoxy resin, a non-phenolic epoxy resin, and derivatives thereof.

Such solid epoxy-based resins, which are commercially available, may include the following. Examples of bisphenol-based solid epoxy resins may include YD-017H, YD-020, YD020-L, YD-014, YD-014ER, YD-013K, YD-019K, YD-019, YD-017R, YD-017, YD-012, YD-011H, YD-011S, YD-011, YDF-2004, YDF-2001 (Kukdo Chemical), etc. Examples of phenolic novolac-based resins may include Epikote 152 and Epikote 154 (Yuka Shell Epoxy Co. LTD.); EPPN-201 (Nippon Kayaku Co., LTD.); DN-483 (Dow Chemical); and YDPN-641, YDPN-638A80, YDPN-638, YDPN-637, YDPN-644, YDPN-631 (Kukdo Chemical), etc. Examples of o-cresol novolac-based resins may include YDCN-500-1P, YDCN-500-2P, YDCN-500-4P, YDCN-500-5P, YDCN-500-7P, YDCN-500-8P, YDCN-500-10P, YDCN-500-80P, YDCN-500-80PCA60, YDCN-500-80PBC60, YDCN-500-90P, YDCN-500-90PA75 (Kukdo Chemical), etc.; EOCN-102S, EOCN-103S, EOCN-104S, EOCN-1012, EOCN-1025, EOCN-1027 (Nippon Kayaku Co. LTD.), etc.; YDCN-701, YDCN-702, YDCN-703, YDCN-704 (Dokdo Chemical Co. LTD.), etc.; and Epiclon N-665-EXP (Dainippon Ink and Chemicals, Inc.), etc. Examples of bisphenol-based novolac epoxy resins may include KBPN-110, KBPN-120, KBPN-115 (Kukdo Chemical), etc. Examples of polyfunctional epoxy resins may include EPPN-501HY, EPPN-502H (Nippon Kayaku Co. LTD.), etc.; and KDT-4400, KDMN-1055, KDMN-1065 (Kukdo Chemical), etc. Examples of amine-based epoxy resins may include Epikote 604 (Yuka Shell Epoxy Co. LTD.), etc.; YH-434 (Dokdo Chemical Co. LTD.), etc.; TETRAD-X, TETRAD-C (Mitsubishi Gas Chemical Company, Inc.), etc.; and ELM-120 (Sumitomo Chemical Company, Ltd.), etc. Examples of heterocycle-containing epoxy resins may include 1,3,5-triglycidyl isocyanurate (PT-810 by Ciba Specialty Chemicals Holding Inc.), etc. Examples of polycyclic aromatic epoxy resins may include 9,10-anthracenediol-1,4-dihydride diglycidyl ether (YX-8800 by Mitsubishi Gas Chemical Company, Inc.), etc. Examples of substituted epoxy resins may include ERL-4234, ERL-4299, ERL-4221, ERL-4206 (UCC Co., Ltd.), etc. Examples of naphthol-based epoxy resins may include: Epiclon HP-4032, Epiclon HP-4032D, Epiclon HP-4700, Epiclon HP-4701 (Dainippon Ink and Chemicals, Inc.), etc. Examples of dicyclopentadiene-based epoxy resins may include Epiclon EXA-7200 (Dainippon Ink and Chemicals, Inc.), TACTIX-556 (Dow Chemical Company), etc. Examples of non-phenolic epoxy resins may include NC-3000, NC-3000H (Nippon Kayaku Co., Ltd.), etc.; and YX-4000, YL-6121 (Mitsubishi Gas Chemical Company Inc.), etc. These epoxy resins may be used singly or in a combination of two or more.

The epoxy resin may be included in the range of 1-30 wt %, preferably, in the range of 2-15 wt % with respect to the total weight of the composition for an encapsulant. Desirable reliability and mechanical properties may be achieved within the above ranges.

In the example embodiment, the curing agent may include a functional group capable of reacting with epoxy resin, and may include, in particular, a functional group capable of forming crosslinks with the cyclic molecule C of a polyrotaxane used as a crosslinking agent. The curing agent used here may be any one known in the related art. For example, as the curing agent, a polyetheramine-based compound, a polyamide-based compound, an amidoamine-based compound, an ethyleneamine-based compound, a cycloaliphatic amine-based compound, an aromatic amine-based compound, a phenolic resin, an anhydride-based compound, and the like may be used singly or in combination.

Such curing agents, which are commercially available, may include the following. Examples of polyetheramine-based curing agents may include JEFFAMINE T-403, JEFFAMINE D-230 (Huntsman Advanced Materials), etc. Examples of polyamide-based curing agents and amidoamine-based curing agents may include VERSAMIDE 125, GENAMID 490 (BASF), etc. Examples of ethyleneamine-based curing agents may include diethylenetriamine (DETA), triethylenetetramine (TETA), tetraehtylenepentamine (TEPA), N-aminoethylpiperazine (AEP), etc. Examples of cycloaliphatic amine-based curing agents may include bis-(p-aminocyclohexyl)methane (PACM), diaminocyclohexane (DACH), etc. Examples of aromatic amine-based curing agents may include methylene dianiline (MDA), methylene bis-(o-ethylaniline) (MBOEA), m-phenylene diamine (M-PDA), diaminophenyl sulfone (DDS), etc.

Examples of the phenolic resin may include a phenolic novolac resin, an alkylphenol novolac resin, bisphenol A novolac resin, a dicyclopentadiene-type phenolic resin, a xylok type phenol resin, a terpene-modified phenolic resin, a cresol/naphthol resin, polyvinylphenols, a phenol/naphthol resin, a a-naphthol scaffold-containing phenolic resin, a triazine-containing cresol novolac resin, a polyfunctional resin, etc. Commercially-available phenolic resins may include the following. Examples of phenolic novolac resins may include HF-4M (Meiwa Plastic Industries, LTD.), etc. Examples of xylok type phenol resins may include MEH-7800 (Meiwa Plastic Industries, LTD.), etc. Examples of polyfunctional resins may include MEH-7500, MEH-7600-4H (Meiwa Plastic Industries, LTD.), etc.

The anhydride-based compound may include tetrahydrophthalic anhydride (THPA), hexahydrophthalic anhydride (HHPA), methyltetrahydrophthalic anhydride (MeTHPA), methylhexahydrophthalic anhydride (MeHHPA), nadicmethyl anhydride (NMA), hydrolyzed methylnadic anhydride (HNMA), phthalic anhydride (PA), or the like.

In the example embodiment, the curing agent may be included in the range of 1-30 wt %, more preferably, in the range of 2-15 wt % with respect to the total weight of the composition for an encapsulant, and desirable reliability and mechanical properties may be achieved within the above ranges. In particular, regarding a molar equivalent ratio of the epoxy resin to the curing agent, a molar equivalent ratio of the epoxy groups of the epoxy resin to all of hydroxyl groups, amine groups, or anhydride groups of the curing agent may be preferably in the range of 0.8-1.2. A degree of curing of the composition, thus, dimensional stability, may be improved within the above ranges.

In the example embodiment, the curing catalyst may be used to shorten a curing time, thereby allowing the epoxy resin and the curing agent to be completely cured while the semiconductor manufacturing process progresses. For example, the curing catalyst may include one, or a mixture of two or more selected from tertiary amines, amine adducts, imidazole-based compounds, organic phosphine- or phosphonium salt-based compounds, boron compounds, organometallic compound, and the like.

Examples of the tertiary amines may include benzyl dimethylamine, triethanolamine, triethylenediamine, diethylaminoethanol, tri(dimethylaminomethyl)phenol, 2-2-(dimethylaminomethyl)phenol, 2,4,6-tris(diaminomethyl)phenol, tri-2-ethylhexyl acid salt, etc. Examples of the amine adducts may include Amicure PN-23, Amicure PN-40, Hardener X-3661S, Hardner X-3670S (Ajinomoto Fine Techno Co., Inc.), etc.; and Novacure HX-3742, Novacure HX-3721 (Asahi Kasei Corporation), etc. Examples of the imidazole-based compounds may include compounds such as 2-methylimidazole, 2-heptadecyl-1H-imidazole, and 2-phenyl-4-methyl-5-dihyroxymethylimidazole, and may include the following commercially-available products: PN-23, PN-40 (Ajinomoto Fine Techno Co., Inc.), etc.; and 2P4MZ, 2MA-OK, 2MAOK-PW, 2P4MHZ (Sakook Chemical Co., Inc.), etc. Examples of the organic phosphine- or phosphonium salt-based compounds may include compounds such as tetraphenylphosphonium tetraphenylborate, tetraphenylphosphonium tetra-p-tolylborate, and tetraphenylphosphonium bromide, and may include, as commercially-available products, TPP-K, TPP-MK, TPP-PB (Hokko Chemical Industry Co., Ltd.), etc. Examples of the boron compounds may include triphenylphosphine tetraphenylborate, tetraphenylborate salt, trifluoroborane-n-hexylamine, trifluoroborane monoethylamine, tetrafluoroborane triethylamine, tetrafluoroborane amine, etc. Examples of organometallic compound may include chromium acetylacetonate, zinc acetylacetonate, nickel acetyl acetonate, etc.

The curing catalyst may be included in the range of 0.01-5 wt %, more preferably, in the range of 0.1-1.5 wt % with respect to the total weight of the composition for an encapsulant. The curing catalyst, when included in the above ranges, may prevent an abrupt curing reaction and may serve to achieve desirable fluidity and shorten the curing time, enabling an efficient encapsulation process.

When forming a wafer level mold during a semiconductor manufacturing process, a thermal stress may occur due to an encapsulant having a higher coefficient of thermal expansion (CTE) than silicon, and this may cause warpage, and even cracks in a semiconductor package. In the example embodiment, the filler may be used to lower the CTE of the composition for an encapsulant, to alleviate contraction when curing the epoxy resin and to improve the strength of the encapsulant.

The filler may have an average particle size in the range of 0.1-45 μm. For example, the filler may include an inorganic filler, such as fumed silica, crystalline silica, and copper coated with alumina or silica, or may include an organic filler such as silicon powder. The filler may have at least one functional group selected from the group consisting of a hydroxyl group, an amino group, and an anhydride group. Alternatively, the filler, before being used, may be surface-reformed so as to have an epoxy group, an oxetane group, or an alkoxysilyl group.

The functional groups of the filler, such as hydroxyl groups, amino groups, or anhydride groups, may react with an epoxy group, an oxetane group, or an alkoxysilyl group of the cyclic molecule C of a polyrotaxane used as a crosslinking agent, to form crosslinks. Also, the filler thus surface-reformed to have an epoxy group, an oxetane group, or an alkoxysilyl group may react with an hydroxyl group, an amino group, or an anhydride group of the cyclic molecule C of a polyrotaxane, to form crosslinks.

The filler may be included in the range of 68-92 wt % with respect to the total weight of the composition of an (semiconductor) encapsulant. The content of the filler of less than 68 wt % may degrade strength of the encapsulant; may not achieve low thermal expansion; and may cause moisture to easily permeate, which is detrimental to reliability characteristics. On the other hand, the content of the filler exceeding 92 wt % may not achieve stress reduction, and may degrade moldability due to diminished fluid characteristics.

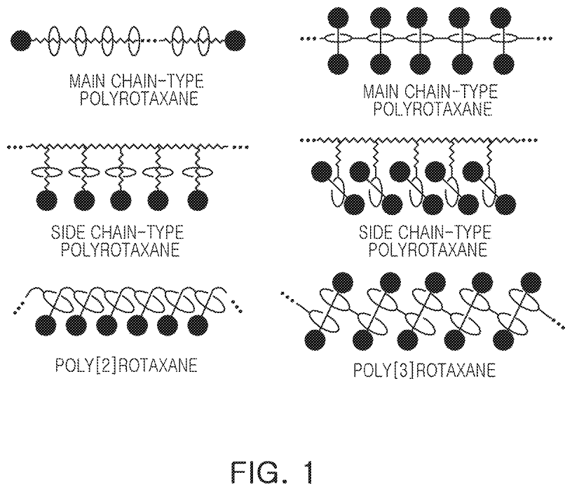

In the example embodiment, the crosslinking agent may include a slide-ring material with crosslinks freely movable within a semiconductor encapsulant. Referring to FIG. 1, the composition for an encapsulant, when containing a slide-ring material, may form freely movable crosslink structures after curing an epoxy resin to thereby distribute and alleviate the stress caused by stretching, bending, or the like. Accordingly, the toughness of an epoxy resin-based semiconductor encapsulant, which critically affects reliability performance of a semiconductor package, may be improved, and further, warpage, which is one of the issues in a wafer level mold caused by thermal stress, may be alleviated. In addition, layer formation and wetting of other materials that come into contact with the semiconductor encapsulant in a subsequent process may be improved.

In the example embodiment, the slide-ring material may be realized by a polyrotaxane. The polyrotaxane includes a linear polymer A, an end group B, and a cyclic molecule C. Depending on the connectivity among the linear polymer A, the end groups B, and the cyclic molecule C, or depending on the number of each component, the polyrotaxane may be classified as a main chain-type polyrotaxane, a side chain-type polyrotaxane, poly[2]rotaxane, or poly[3]rotaxane, which may be used without limitation in the example embodiment.

In the example embodiment, the polyrotaxane may include a linear polymer A, an end group B, and a cyclic molecule C threaded through by the linear polymer A. The linear polymer A may include a side chain, and the cyclic molecule C may be present on a main chain or a side chain of the linear polymer A.

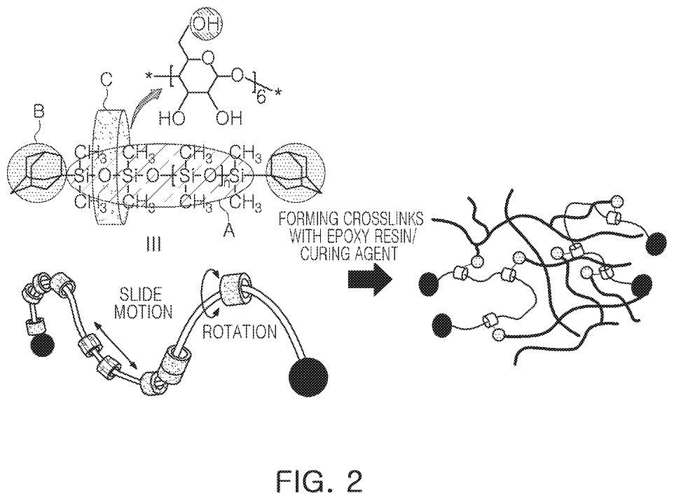

Referring to FIG. 2, the polyrotaxane may have a structure in which the end group B is present at both ends of the linear polymer A, or a structure in which the end group B is present at one end of a side chain of the linear polymer A, the other end of the side chain being capped by a main chain of the linear polymer A. Alternatively, the end group B may be present at one side of the linear polymer A, the other end of the linear polymer A being capped by another cyclic molecule C.

The cyclic molecule C may be unable to depart from the linear polymer A through the end group B, the main chain of the linear polymer A, or another cyclic molecule C, while being able to rotate or slide along the axis of the linear polymer A in response to a temperature change or an external stimulus.

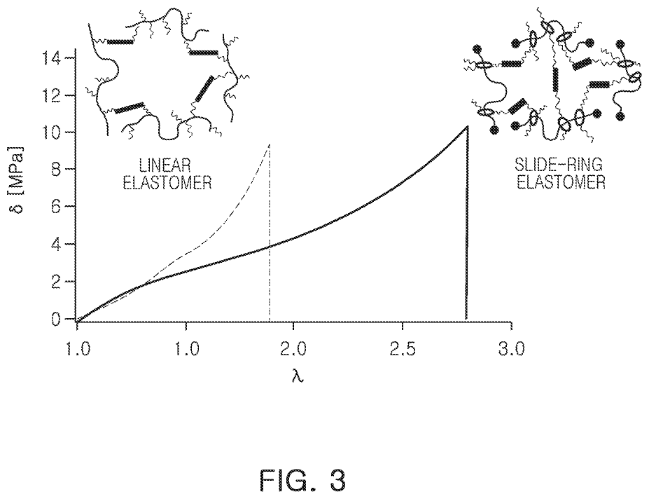

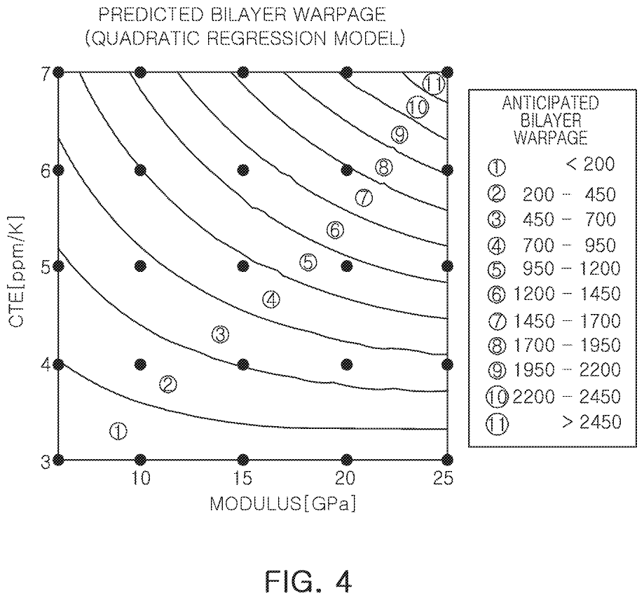

Referring to FIG. 3, the epoxy-cured product using a conventional crosslinking agent having a linear structure had an issue in that brittleness increases as crosslink density increases (see, e.g., “linear elastomer” in upper left region of FIG. 3 and dashed graph line). However, by using the polyrotaxane in the example embodiment, it is possible to improve the toughness of a semiconductor encapsulant while maintaining a desired crosslink density through controlling the number of cyclic molecules C or the number of reactive functional groups in the cyclic molecules C, as the cyclic molecules C rotate or freely slide along the axes of the linear polymers A, thereby distributing stress (see, e.g., “slide-ring elastomer” in upper right region of FIG. 3 and solid graph line). Also, referring to FIG. 4, by adding a polyrotaxane and thereby reducing the Young's modulus E of a semiconductor encapsulant, it is possible to alleviate the warpage of a semiconductor encapsulant, and consequently prevent crack formation.

In the example embodiment, the linear polymer A of polyrotaxane may be a polymer having a chain structure, and may be a polysiloxane, a polyethylene glycol, a polybutadiene, or a combination thereof. The linear polymer A may include a functional group reactive with a precursor of the end group B, to bond with the end group B. This reactive functional group may be appropriately selected among functional groups that can react with the precursor of the end group B, and yet do not react with the functional groups of the cyclic molecule C, preferably.

The end group B may react with functional groups present on both ends of the linear polymer A to bond with the ends of the linear polymer A, and may be any functional group as long as it has a structure bulky enough to prevent the cyclic molecule C from departing from the linear polymer A. Preferably, the end group B may include one or more selected from the group consisting of an adamantyl group, a silsesquioxanyl group, a phenyl group, a substituted or unsubstituted benzyl group, a cyclodextrinyl group, and a silane group, wherein a substituent group of the benzyl group may include one or more selected from the group consisting of an alkyl group having 1-5 carbon atoms, a hydroxyl group, a halogen group, a cyano group, a sulfonyl group, a carboxyl group, an amino group, a phenyl group, and an ester group.

The cyclic molecule C may have a functional group capable of reacting with an epoxy resin, a curing agent, or a filler, to form crosslinks. Preferably, the cyclic molecule C may have at least one functional group selected from the group consisting of an epoxy group, an oxetane group, and an alkoxysilyl group, or may have a functional group capable of reacting with the at least one functional group.

Among the functional groups of the cyclic molecule C, the at least one functional group selected from the group consisting of an epoxy group, an oxetane group, and an alkoxysilyl group, may react with a filler to form crosslinks, the filler having one or more functional group selected from the group consisting of a hydroxyl group, an amino group, and an anhydride group.

Also, the functional group capable of reacting with the at least one functional group of the cyclic molecule C, selected from the group consisting of an epoxy group, an oxetane group, and an alkoxysilyl group, may include one or more selected from the group consisting of a hydroxyl group, an amino group, and an anhydride group. Further, the functional group may react and form crosslinks with the filler that is surface-reformed to have an epoxy group, an oxetane group, or an alkoxysilyl group.

The molar equivalent ratio of the linear polymers A to the cyclic molecules C in a polyrotaxane of the example embodiment is a factor that affects stress relaxation characteristics of a composition for a semiconductor encapsulant, and the molar equivalent ratio is determined on the basis of a length of the linear polymer A and a width of the cyclic molecule C. In an example embodiment, a molar equivalent ratio of the cyclic molecules C to the linear polymers A may be, preferably, 2 or greater, so as to allow freely movable crosslink structures to form after curing epoxy resin.

In the example embodiment, an inclusion rate may be defined as a ratio of the number N′ of cyclic molecules C actually included in the linear polymer A of the polyrotaxane to a maximum number N of cyclic molecules C that can be included. When the number N′ of cyclic molecules C, which are actually included in the linear polymer A, is in the range of 2 or greater, the inclusion rate may be in the range of 0.05-0.70, more preferably, in the range of 0.10-0.50. The inclusion rate of less than 0.05 may cause an undesirable decrease in mobility of crosslinks and stress distribution after curing epoxy resin; however, when the inclusion rate exceeds 0.70, the cyclic molecules C may be disposed excessively densely, thus causing mobility of the cyclic molecules C to diminish. The inclusion rate may be appropriately controlled by a method known in the related art.

In the example embodiment, a molecular weight of the linear polymer A may be in the range of 1,000-100,000, preferably, in the range of 3,000-40,000. The molecular weight of less than 1,000 may cause mobility of crosslinks and heat resistance to diminish after curing, whereas the molecular weight exceeding 100,000 may undesirably degrade fluidity and handling ease of the composition for an encapsulant. The molecular weight here may be a converted molecular weight with respect to a standard polystyrene, as measured by gel permeation chromatography.

In the example embodiment, the crosslinking agent may be included in the range of 0.01-7 wt %, preferably in the range of 0.05-5 wt % with respect to the total weight of the composition for an encapsulant. The content of the crosslinking agent of less than 0.01 wt % may fail to form sufficient crosslinks with the epoxy resin, the curing agent, or the filler, thus lessening the effects of improving toughness and stress distribution, and possibly causing warpage; however, the content of the crosslinking agent exceeding 7 wt % may degrade flow characteristics of the composition for an encapsulant, possibly leading to a poor yield during encapsulant preparation and packaging processes.

The composition for an encapsulant in the example embodiment, according to intended purposes, may further include various additives commonly used in a thermosetting resin composition, in addition to the epoxy resin, the curing catalyst, the filler, and the polyrotaxane described above. Such additives may include a softening agent, a flux, a toughening agent, a bond promoter, a dispersing agent, a coloring agent, and the like, wherein the content of such additives may be adjusted as desired.

In the example embodiment, depending on the properties of each component of the composition for an encapsulant, an original form of the semiconductor encapsulant may be liquid, solid in a powder form, solid in a granule form, or solid in a film form.

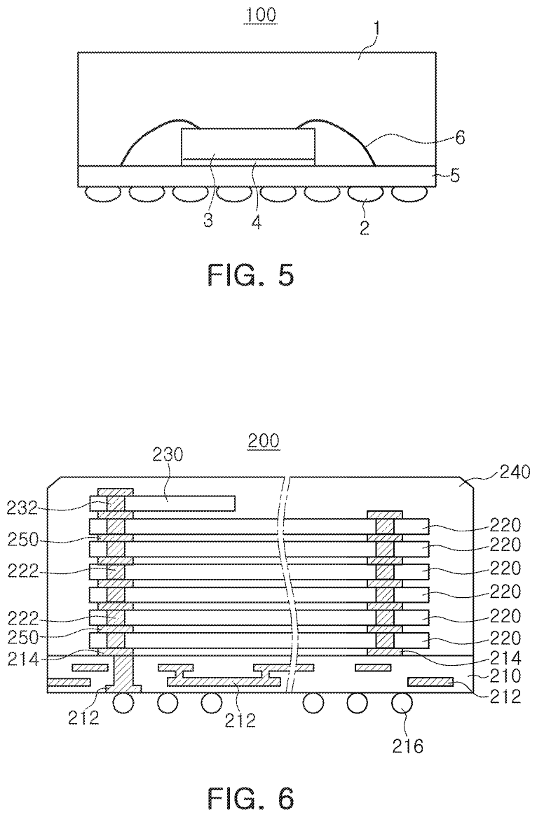

FIG. 5 is a cross-sectional view of a structure of a semiconductor package that can be employed with a semiconductor encapsulant according to the example embodiment. Referring to FIG. 5, a semiconductor package 100 may include: a substrate 5; a die attach film 4 disposed on the substrate 5; a chip 3 disposed on the substrate 5 and attached to the substrate 5 through the die attach film 4; a connection part 6, such as a bonding wire, for electrically connecting the chip 3 and the substrate 5 to each other; and a encapsulant 1 encapsulating the chip 3 and the connection part 6, while protecting the substrate 5 and mounted structures including the connection part 6 and the chip 3 mounted on the substrate 5. The encapsulant 1 may be formed to completely cover the chip 3 and the connection part 6 on the substrate 5.

The encapsulant 1 is obtained from a composition for an encapsulant according to an example embodiment. By using a composition for an encapsulant of an example embodiment, thermal stress may be reduced when forming a wafer level mold, and thus, warpage of the semiconductor encapsulant may be alleviated.

FIG. 6 is a cross-sectional view of an integrated circuit device using a semiconductor package that can be employed in an encapsulant according to an example embodiment. Referring to FIG. 6, an integrated circuit device 200 may include a package substrate 210 including substrate internal wirings 212, connection terminals 214, and solder balls 216, and a plurality of semiconductor chips 220 sequentially stacked on the package substrate 210 and connection structures 222 and 232. The plurality of semiconductor chips 220 and connection structures 222 and 232 may be electrically connected to the connection terminals 214 of the package substrate 210 by connection portions 250 such as bumps.

A control chip 230 may be connected on the plurality of semiconductor chips 220. A stacked structure of the plurality of semiconductor chips 220 and the control chip 230 may be encapsulated by encapsulant 240 on the package substrate 210. The encapsulant 240 may have a configuration similar to that of the encapsulant 1, described with reference to FIG. 5.

The encapsulant 240 may contain a composition for an encapsulant according to an example embodiment. By using the composition for an encapsulant according to an example embodiment, thermal stress may be reduced when forming a wafer level mold, and thus, warpage of the semiconductor encapsulant may be alleviated.

Meanwhile, an example embodiment relates to an epoxy resin composition. In some embodiments, the epoxy resin composition may contain an epoxy resin, a curing agent, a curing catalyst, a filler, and a crosslinking agent, and may further contain an additive necessary for improving properties of the epoxy resin.

The epoxy resin composition according to an example embodiment, in addition to being used as semiconductor encapsulant, may be used in various other fields relating to adhesives, paints, laminates, casting material, and molding material, and the like.

A Young's modulus E of the epoxy resin may be within the range of 7-20 GPa. The Young's modulus of less than 7 GPa may make it difficult to procure mechanical stability from an external source; however, the Young's modulus exceeding 20 GPa may cause excessive warpage of a wafer, causing handling difficulties during the progress of a process. Accordingly, the Young's modulus E of the epoxy resin outside the above range may not be preferable.

In the example embodiment, a fracture toughness of the epoxy resin may be in the range of 0.3-10 MPa·m^{1/2}. The fracture toughness of less than 0.3 MPa·m^{1/2} may make it difficult to procure mechanical stability from an external source; however, the fracture toughness exceeding 10 MPa·m^{1/2} may degrade processability due to limitations of achievable composition. Accordingly, the fracture toughness of the epoxy resin outside the above range may not be preferable.

### Example

### 1. Preparation of Polyrotaxane

### Synthesis Example

Diamino polyethylene glycol (Diamino PEG) (7.2 g) having an average molecular weight of 35,000 was added to a solution containing a-cyclodextrin (41 g) dissolved in water, and the solution was agitated at room temperature for 2 days. White precipitation obtained through centrifugation of the solution was freeze-dried to evaporate and remove water therefrom. The white solid product thus produced (pseudorotaxane) was dissolved in anhydrous N,N-dimethylformamide (DMF) (65 mL). 1-adamantanecarboxylic acid (0.19 g), BOP [(benzotriazol-1-yloxy)-tris(dimethylamino) phosphonium hexafluorophosphate] (0.47 g), and DIPEA (N,N-diisopropylethylamine) (0.19 mL) were dissolved in anhydrous DMF (5 mL), and this was slowly dropped onto the white solid product dissolved in anhydrous DMF. After agitating for two days, residual organic solvents were removed by dialysis using dimethyl sulfoxide (DMSO) and water, along with freeze-drying, and a polyrotaxane was obtained as a precipitate, the polyrotaxane being milk-white in color. The polyrotaxane thus synthesized was found to have an inclusion rate of 0.21, including 38 α-cyclodextrin molecules per axis of polyethylene glycol molecule, as measured through ¹H-NMR analysis.

### 2. Preparation of Composition for Encapsulant and Preparation of Encapsulants

### Example 1

A phenol novolac resin represented by chemical formula 1 and a polyfunctional resin represented by chemical formula 2 were combined in a 3:1 ratio to prepare an epoxy resin, and the phenol novolac resin and the polyfunctional resin were combined in 5:1 ratio to prepare a phenol resin-based curing agent. Next, 5 wt % of the epoxy resin, 4 wt % of a curing agent, 90 wt % of amorphous silica serving as filler, and 0.3 wt % of a coloring agent were dispersed and roll mixed with 1.2 wt % of the polyrotaxane synthesized in Synthesis Example, to prepare a composition for an encapsulant.

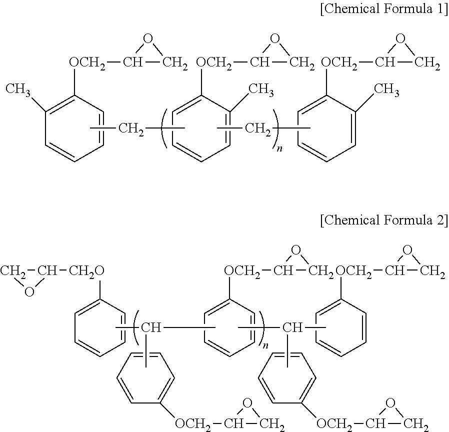

By using an epoxy mold compound (EMC) formed of the composition, a wafer was molded at 135° C. for 600 seconds, and subsequently, post-cured at 150° C. for 2 hours to prepare a semiconductor encapsulant.

### Comparative Example 1

An epoxy resin and a curing agent were prepared under the same conditions as in Example 1. Next, 5 wt % of the epoxy resin, 4 wt % of a curing agent, 90 wt % of amorphous silica serving as filler, and 0.3 wt % of a coloring agent were dispersed in and roll mixed with 1.2 wt % of silicone oil (epoxy and polyether modified dimethylsiloxane, Dow Corning, Toray SF 8421 EG Fluid) to prepare a composition for an encapsulant.

By using an epoxy mold compound (EMC) formed of this composition, a wafer was molded at 135° C. for 600 seconds, and subsequently, post-cured at 150° C. for 2 hours to produce a semiconductor encapsulant.

### Comparative Example 2

A composition for an encapsulant was prepared under the same conditions as in Comparative Example 1, except for containing 0.96 wt % of silicone oil. By using this composition, a semiconductor encapsulant was produced.

### Comparative Example 3

A composition for an encapsulant was synthesized under the same conditions as in Comparative Example 1, except for containing 0.72 wt % of silicone oil. By using this composition, a semiconductor encapsulant was produced.

### 3. Appearance Defect Test

The semiconductor encapsulants prepared in Example 1 and Comparative Examples 1-3 were inspected for the presence of an appearance defect. The semiconductor encapsulants were placed on a hot plate and heated, and as shown in Table 1, “O” indicates that an appearance defect occurred, whereas “X” indicates that no appearance defect occurred.

TABLE 1
The Presence of Appearance Defect on the Semiconductor Encapsulants

| Heating | | Comparative | Comparative | Comparative |
|---|---|---|---|---|
| Temperature | Example 1 | Example 1 | Example 2 | Example 3 |
| 140° C. | X | X | X | X |
| 160° C. | X | X | X | X |
| 180° C. | X | X | X | X |
| 200° C. | X | X | X | X |
| 220° C. | X | X | X | X |
| 240° C. | X | X | X | X |
| 260° C. | X | ◯ | ◯ | X |
| 280° C. | X | ◯ | ◯ | X |
| 300° C. | X | ◯ | ◯ | X |

### 4. Measurement of Young's Modulus E

The Young's modulus E of the semiconductor encapsulants prepared in Example 1 and Comparative Examples 1-3, measured at 25° C. and 260° C., respectively, and the results are presented in Table 2.

The Young's modulus E was calculated using Equation 1, where Lv, W, and H values were each measured using a micrometer, and a P/Y value was measured using a TENSILON flexural strength testing machine.

$$E = \frac{{Lv}^{3}}{4 \times W \times {H}^{3}} \times P / Y \qquad Equation 1$$

Lv=Span of Support

W=Width of Test Specimen

H=Height of Test Specimen

P/Y=Gradient of Load-deflection Curve

TABLE 2
The Young's Modulus of the Semiconductor Encapsulants

| | | Comparative | Comparative | Comparative |
|---|---|---|---|---|
| Temperature | Example 1 | Example 1 | Example 2 | Example 3 |
| 25° C. (GPa) | 11 | 15 | 20 | 12 |
| 260° C. (GPa) | 0.11 | 0.14 | 0.17 | 0.11 |

### 5. Measurement of Warpage

The wafer warpage of samples of the semiconductor encapsulants prepared in Example 1 and Comparative Examples 1-3, as measured using a Shadow Moird technique (AKROMETRIX Thermoire AXP), are presented in Table 3.

TABLE 3
Wafer Warpage of the Semiconductor Encapsulants

| | | Comparative | Comparative | Comparative |
|---|---|---|---|---|
| | Example 1 | Example 1 | Example 2 | Example 3 |
| Warpage | 463 | 480 | 1200 | 1605 |
| (μm) | | | | |

### 6. Dielectric Layer Coating Test

On surfaces of the EMCs prepared in Example 1 and Comparative Examples 1-3, a dielectric layer was formed to a thickness of 5 μm by spin coating, and post-cured at 320° C. for 1.5 hour, and the appearance thereof was inspected with the naked eye.

In Example 1, the dielectric layer was uniformly coated on the surface of the EMC, and thus, repelling and dewetting issues did not arise, whereas in Comparative Examples 1-3, wettability was reduced due to a difference in surface energy between the EMC and the dielectric layer, which is hydrophilic, and thus, repelling and dewetting issues were observed.

According to example embodiments of the present inventive concept, there may be provided a composition for a semiconductor encapsulant capable of suppressing the formation of appearance defects, improving toughness, and reducing warpage, by comprising a polyrotaxane to form crosslinks with epoxy resin.

While example embodiments have been shown and described above, it will be apparent to those skilled in the art that modifications and variations could be made without departing from the scope of the present inventive concept as defined by the appended claims.

What is claimed is:

1. A semiconductor package, comprising:
a substrate;
at least one semiconductor chip on the substrate; and
a semiconductor encapsulant covering the at least one semiconductor chip,
wherein the semiconductor encapsulant comprises:
an epoxy resin;
a curing agent;
a filler; and
a polyrotaxane,
wherein the polyrotaxane includes a linear polymer A, an end group B, and a cyclic molecule C threaded through by the linear polymer A, and
wherein the cyclic molecule C has at least one functional group selected from the group consisting of an epoxy group, an oxetane group, and an alkoxysilyl group, or has a functional group capable of reacting with the at least one functional group.

2. The semiconductor package of claim 1, wherein the linear polymer A is a polysiloxane, a polyethylene glycol, a polybutadiene, or a combination thereof.

3. The semiconductor package of claim 1, wherein the end group B is at least one selected from the group consisting of an adamantyl group, a silsesquioxanyl group, a phenyl group, a substituted or unsubstituted benzyl group, a cyclodextrinyl group, and a silane group.

4. The semiconductor package of claim 1, wherein the polyrotaxane has a structure in which the end group B is present on both ends of the linear polymer A, a structure in which the end group B is present on one end of a side chain of the linear polymer A, the other end of the side chain being capped by a main chain of the linear polymer A, or a structure in which the end group B is present on one side of the linear polymer A, the other end of the linear polymer A being capped by another cyclic molecule C.

5. The semiconductor package of claim 1, wherein the cyclic molecule C is present on a main chain or a side chain of the linear polymer A.

6. The semiconductor package of claim 1, wherein the functional group capable of reacting with the at least one functional group of the cyclic molecule C, selected from the group consisting of an epoxy group, an oxetane group, and an alkoxysilyl group, is at least one selected from the group consisting of a hydroxyl group, an amino group, and an anhydride group.

7. The semiconductor package of claim 1, wherein the functional group is present on a main chain, a side chain, or a grafted chain of the cyclic molecule C.

8. The semiconductor package of claim 1, wherein two or more cyclic molecules C are included in each linear polymer A.

9. The semiconductor package of claim 1, wherein the filler has at least one functional group selected from the group consisting of a hydroxyl group, an amino group, and an anhydride group.

10. The semiconductor package of claim 1, wherein the composition for the semiconductor encapsulant includes, with respect to a total weight of the composition for a semiconductor encapsulant, 1-30 wt % of the epoxy resin, 1-30 wt % of the curing agent, 68-92 wt % of the filler, and 0.01-7 wt % of the polyrotaxane.

11. The semiconductor package of claim 1, wherein a molar equivalent ratio of epoxy groups present in the epoxy resin to all hydroxyl groups, amine groups, or anhydride groups present in the curing agent is in a range of 0.8-1.2.

12. The semiconductor package of claim 1, further comprising a curing catalyst, wherein a content of the curing catalyst is in a range of 0.01-5 wt % with respect to a total weight of the composition for a semiconductor encapsulant.

13. The semiconductor package of claim 1, wherein an inclusion rate of the polyrotaxane is in a range of 0.05-0.07.

14. The semiconductor package of claim 1, wherein a molecular weight of the linear polymer A is in a range of 1,000-100,000.

15. The semiconductor package of claim 1, wherein the polyrotaxane is at least one selected from the group consisting of a main chain-type polyrotaxane, a side chain-type polyrotaxane, poly[2]rotaxane, and poly[3]rotaxane.

16. An epoxy resin composition comprising:
an epoxy resin;
a curing agent;
a filler; and
a polyrotaxane,
wherein the polyrotaxane includes a linear polymer A, an end group B, and a cyclic molecule C threaded through by the linear polymer A, and
wherein the cyclic molecule C has at least one functional group selected from the group consisting of an epoxy group, an oxetane group, and an alkoxysilyl group, or has a functional group capable of reacting with the at least one functional group.

17. The epoxy resin composition of claim 16, wherein the epoxy resin composition includes, with respect to a total weight of the epoxy resin composition, 1-30 wt % of the epoxy resin, 1-30 wt % of the curing agent, 68-92 wt % of the filler, and 0.01-7 wt % of the polyrotaxane.

18. The epoxy resin composition of claim 16, wherein a Young's modulus of the epoxy resin composition is in a range of 7-20 GPa.

19. The epoxy resin composition of claim 16, wherein a fracture toughness of the epoxy resin composition is in a range of 0.3-10 Mpa·m^{1/2}.

20. An epoxy resin composition, comprising:
an epoxy resin;
a curing agent;
a filler; and
a polyrotaxane,
wherein the polyrotaxane includes a linear polymer A, an end group B, and a cyclic molecule C threaded through by the linear polymer A,
wherein the linear polymer A is a polysiloxane, a polyethylene glycol, a polybutadiene, or a combination thereof,
wherein the end group B is at least one selected from the group consisting of an adamantyl group, a silsesquioxanyl group, a phenyl group, a substituted or unsubstituted benzyl group, a cyclodextrinyl group, and a silane group, and
wherein the cyclic molecule C has at least one functional group selected from the group consisting of an epoxy group, an oxetane group, and an alkoxysilyl group, or has a functional group capable of reacting with the at least one functional group.
